(19) United States
(12) Patent Application Publication
(10) Pub. No.: US 2008/0308913 A1
(43) Pub. Date: Dec. 18, 2008

(54) STACKED SEMICONDUCTOR PACKAGE AND METHOD OF MANUFACTURING THE SAME

(75) Inventors: Sang-Wook PARK, Chungcheongnam-do (KR); Min-Young SON, Chungcheongnam-do (KR); Jong-Gi LEE, Gyeonggi-do (KR); Kun-Dae YEOM, Chungcheongnam-do (KR); Sung-Ki LEE, Chungcheongnam-do (KR); Ji-Seok HONG, Seoul (KR)

Correspondence Address: MARGER JOHNSON & MCCOLLOM, P.C., 210 SW MORRISON STREET, SUITE 400, PORTLAND, OR, 97204, US

(73) Assignee: Samsung Electronics Co., Ltd., Gyeonggi-do (KR)

(21) Appl. No.: 12/140,190

(22) Filed: Jun. 16, 2008

(30) Foreign Application Priority Data
Jun. 15, 2007 (KR) 2007-58847

(51) Int. Cl. H01L 23/495

(52) U.S. Cl. 257/666; 257/E23.042

(57) ABSTRACT

A stacked semiconductor package includes a first semiconductor package, a second semiconductor package and a conductive connection member. The first semiconductor package includes a first semiconductor chip, a first lead frame having first outer leads that are electrically connected to the first semiconductor chip, and a first molding member formed on the first semiconductor chip and the first lead frame to expose the first outer leads. The second semiconductor package includes a second semiconductor chip, a second lead frame formed on the first molding member and having second outer leads that may be electrically connected to the second semiconductor chip, and a second molding member formed on the second semiconductor chip and the second lead frame to expose the second outer leads. The conductive connection member may electrically connect the first outer leads and the second outer leads to each other. Further, the conductive connection member may have a crack-blocking groove.

### CROSS-REFERENCE TO RELATED APPLICATIONS

This application claims priority under 35 U.S.C. §119 to Korean Patent Application No. 2007-58847 filed on Jun. 15, 2007 in the Korean Intellectual Property Office (KIPO), the contents of which are herein incorporated by reference in their entirety.

### BACKGROUND OF THE INVENTION

1. Field of the Invention

Example embodiments of the present invention relate to a stacked semiconductor package and a method of manufacturing the same. More particularly, example embodiments of the present invention relate to a stacked semiconductor package electrically connected to each other through a lead frame, and a method of manufacturing the stacked semiconductor package.

2. Description of the Related Art

Generally, various semiconductor processes may be performed on a wafer to form a plurality of semiconductor chips. To mount the semiconductor chips on a printed circuit board (PCB), a packaging process may be performed on the wafer to form semiconductor packages.

One method for increasing a storage capacity of the semiconductor package includes sequentially stacking a plurality of semiconductor chips. Outer leads of each of the semiconductor packages may be electrically connected to each other by a soldering process such that the semiconductor chips are electrically connected to each other.

In a conventional stacked semiconductor package, a soldering portion covering the outer leads may be of one body. Thus, when a crack is generated in the soldering portion due to stresses applied to the semiconductor package, the crack may spread along the soldering portion. The crack may damage the soldering portion so that electrical contacts between the outer leads may be cut off. Particularly, since the stresses may be concentrated on an edge portion of the semiconductor package, the crack may be generated in a concentrated area, i.e., in an outermost outer lead of the outer leads.

Further, the conventional outer lead may have an “L” shape. When a solder is coated on the L-shaped outer lead, the solder may fall from a surface of the L-shaped outer lead. As a result, the solder on the L-shaped outer lead may be too little in amount or may not exist at all. As a result, the electrical contacts between the outer lead may be cut off.

### SUMMARY OF THE INVENTION

Some embodiments of the present invention provide a stacked semiconductor package that is capable of suppressing spreads of cracks to ensure an electrical contact between outer leads.

Some embodiments of the present invention also provide a method of manufacturing the above-mentioned stacked semiconductor package.

A stacked semiconductor package in accordance with one aspect of the present invention may include a first semiconductor package, a second semiconductor package and a conductive connection member. The first semiconductor package may include a first semiconductor chip, a first lead frame having first outer leads that are electrically connected to the first semiconductor chip, and a first molding member formed on the first semiconductor chip and the first lead frame to expose the first outer leads. The second semiconductor package may include a second semiconductor chip, a second lead frame formed on the first molding member and having second outer leads that are electrically connected to the second semiconductor chip, and a second molding member formed on the second semiconductor chip and the second lead frame to expose the second outer leads. The conductive connection member electrically connects the first outer leads and the second outer leads exposed by the first molding member and the second molding member, respectively, to each other. Further, the conductive connection member may have a crack-blocking groove for blocking spreads of cracks generated in the conductive connection member.

According to one example embodiment, each of the first outer leads may have a lower surface exposed by the first molding member. The crack-blocking groove may be formed at a portion of the conductive connection member on the lower surfaces of the first outer leads. Further, the crack-blocking groove may be arranged along a direction substantially perpendicular to an extending direction of the first outer leads. The first outer leads may be exposed through the crack-blocking groove to divide the conductive connection member into two portions by the crack-blocking groove.

According to another example embodiment, first outermost leads, which are arranged at edge portions of the first semiconductor chip, of the first outer leads may have a linear shape extending along a horizontal direction. Further, upper surfaces of the first linear outermost leads may be covered with the conductive connection member. Furthermore, the second outer leads adjacent to the first linear outermost leads may be electrically insulated from the first linear outermost leads.

According to still another example embodiment, the first semiconductor chip and the first outer leads may be electrically connected to each other via conductive wires. Further, the second conductor chip and the second outer leads may be electrically connected to each other via conductive wires.

In a method of manufacturing a stacked semiconductor package in accordance with one aspect of the present invention, a first semiconductor package is prepared. Here, the first semiconductor package includes a first semiconductor chip, a first lead frame having first outer leads that are electrically connected to the first semiconductor chip, and a first molding member formed on the first semiconductor chip and the first lead frame to expose the first outer leads. A second semiconductor package is stacked on the first semiconductor package. Here, the second semiconductor package includes a second semiconductor chip, a second lead frame formed on the first molding member and having second outer leads that are electrically connected to the second semiconductor chip, and a second molding member formed on the second semiconductor chip and the second lead frame to expose the second outer leads. The first outer leads and the second outer leads exposed by the first molding member and the second molding member, respectively, are covered with a conductive connection member having a crack-blocking groove to electrically connect the first outer leads and the second outer leads to each other.

According to one example embodiment, preparing the first semiconductor package may include attaching the first semiconductor chip on the first lead frame, electrically connecting the first semiconductor chip to the first outer leads, and forming the first molding member on the first semiconductor chip and the first outer leads to expose the first outer leads. Further, the first semiconductor chip and the first outer leads may be electrically connected to each other using first conductive wires.

According to another example embodiment, preparing the second semiconductor package may include attaching the second semiconductor chip on the second lead frame, electrically connecting the second semiconductor chip to the second outer leads, and forming the second molding member on the second semiconductor chip and the second outer leads to expose the second outer leads. Further, the second semiconductor chip and the second outer leads may be electrically connected to each other using second conductive wires.

According to still another example embodiment, covering the first outer leads with the conductive connection member may include forming the conductive connection member on the first outer leads, and partially etching the conductive connection member to form the crack-blocking groove exposing the first outer leads.

According to yet still another example embodiment, first outermost leads, which are arranged at edge portions of the first semiconductor chip, of the first outer leads may have a linear shape extending along a horizontal direction. Further, upper surfaces of the first linear outermost leads may be covered with the conductive connection member. Furthermore, the conductive connection member may be formed only on the first linear outer leads to electrically isolate the second outer leads adjacent to the first linear outermost leads from the first linear outermost leads. Moreover, ends of the first linear outermost leads may be partially removed to provide the first linear outermost leads and the first outer leads with substantially the same protruded length from the first molding member.

A stacked semiconductor package in accordance with still another aspect of the present invention includes a first semiconductor package, a second semiconductor package and a conductive connection member. The first semiconductor package may include a first semiconductor chip, a first lead frame having first central outer leads that are electrically connected to the first semiconductor chip and first linear outermost leads extending along a horizontal direction, and a first molding member formed on the first semiconductor chip and the first lead frame to expose the first central outer leads and the first linear outermost leads. The second semiconductor package may include a second semiconductor chip, a second lead frame formed on the first molding member and having second outer leads that are electrically connected to the second semiconductor chip, and a second molding member formed on the second semiconductor chip and the second lead frame to expose the second outer leads. The conductive connection member may be formed on the first central outer leads and the second outer leads to electrically connect the first central outer leads and the second outer leads to each other. Further, the conductive connection member may be formed only on the second outer leads adjacent to the first linear outermost leads to electrically isolate the second outer leads adjacent to the first linear outermost leads from the first linear outermost leads.

In a method of manufacturing a stacked semiconductor package in accordance with yet still another aspect of the present invention, a first semiconductor package is prepared. The first semiconductor package may include a first semiconductor chip, a first lead frame having first central outer leads that are electrically connected to the first semiconductor chip and first linear outermost leads extending along a horizontal direction, and a first molding member formed on the first semiconductor chip and the first lead frame to expose the first central outer leads and the first linear outermost leads. A second semiconductor package may be stacked on the first semiconductor package. The second semiconductor package may include a second semiconductor chip, a second lead frame formed on the first molding member and having second outer leads that are electrically connected to the second semiconductor chip, and a second molding member formed on the second semiconductor chip and the second lead frame to expose the second outer leads. The conductive connection member may be formed on the first central outer leads and the second outer leads to electrically connect the first central outer leads and the second outer leads to each other, and only on the second outer leads adjacent to the first linear outermost leads to electrically isolate the second outer leads adjacent to the first linear outermost leads from the first linear outermost leads.

According to the present invention, the conductive connection member for electrically connecting the outer leads to each other may have the crack-blocking groove so that spreads of cracks generated in the conductive connection member may be blocked by the crack-blocking member. Thus, electrical contacts between the outer leads caused by damages of the conductive connection member may not be cut off. Further, since the outermost leads may have the linear shape, the conductive connection member on the upper surface of the linear outer leads may have a sufficient thickness.

### BRIEF DESCRIPTION OF THE DRAWINGS

The above and other features and advantages of the present invention will become readily apparent by reference to the following detailed description when considered in conjunction with the accompanying drawings, wherein:

FIG. 1 is a perspective view illustrating a stacked semiconductor package in accordance with an example embodiment of the present invention;

FIG. 2 is an enlarged perspective view of a portion “II” in FIG. 1;

FIG. 3 is a cross-sectional view taken along a line III-III′ in FIG. 1;

FIG. 4 is a cross-sectional view taken along a line IV-IV′ in FIG. 1; and

FIGS. 5 to 16 are cross-sectional views illustrating a method of manufacturing the stacked semiconductor package in FIG. 1.

### DESCRIPTION OF THE EMBODIMENTS

The present invention is described more fully hereinafter with reference to the accompanying drawings, in which example embodiments of the present invention are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Stacked Semiconductor Package

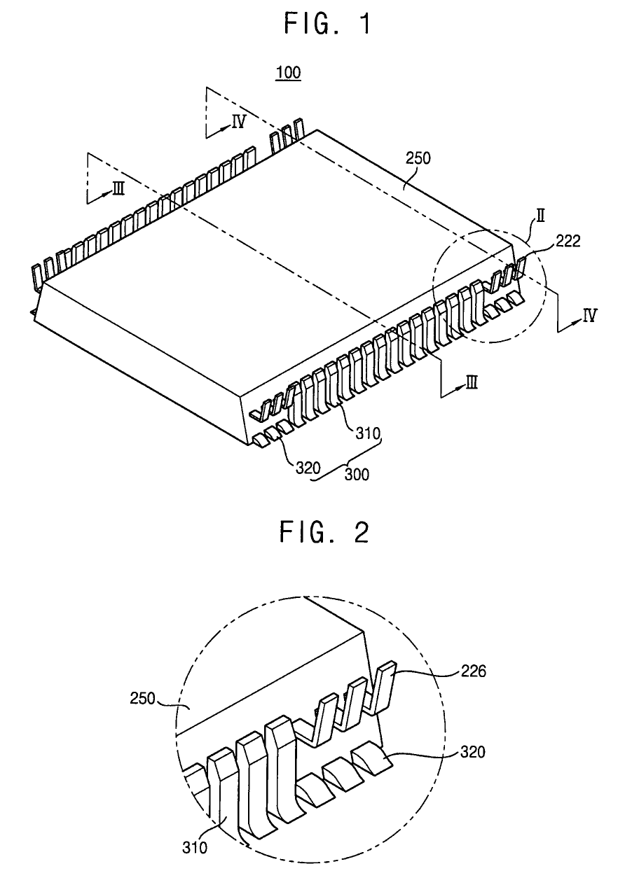

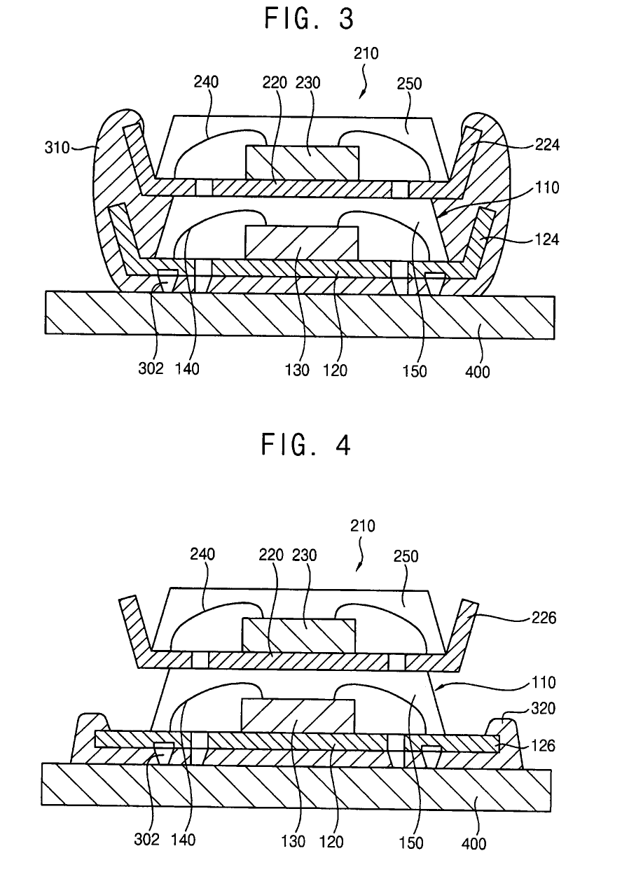

FIG. 1 is a perspective view illustrating a stacked semiconductor package in accordance with an example embodiment of the present invention. FIG. 2 is an enlarged perspective view of a portion “II” in FIG. 1. FIG. 3 is a cross-sectional view taken along a line III-III′ in FIG. 1. And FIG. 4 is a cross-sectional view taken along a line IV-IV′ in FIG. 1.

Referring to FIGS. 1 to 4, a stacked semiconductor package 100 of this example embodiment may include a first semiconductor package 110, a second semiconductor package 210, and a conductive connection member 300.

The first semiconductor package 110 includes a first lead frame 120, a first semiconductor chip 130, first conductive wires 140 and a first molding member 150.

The first lead frame 120 includes a conductive material. The first lead frame 120 has first outer leads 122. The first outer leads 122 are arranged at both sides of the first lead frame 120. The first outer leads 122 include first central outer leads 124 arranged at a central portion of the first lead frame 120, and first outermost leads 126 arranged at an edge portion of the first lead frame 120. Each of the first central outer leads 124 has an upwardly bent shape. In this example embodiment, the first central outer leads 124 may have an “L” shape. In contrast, each of the first outermost leads 126 has a linear shape extending along a horizontal direction.

The first semiconductor chip 130 is attached to a central upper surface of the first lead frame 120. In this example embodiment, the first semiconductor chip 130 may be attached to the central upper surface of the first lead frame 120 using an adhesive (not shown). Further, a plurality of bonding pads (not shown) may be formed on an upper surface of the first semiconductor chip 130.

The first conductive wires 140 electrically connect the bonding pads of the first semiconductor chip 130 to the first outer leads 122 in a one-to-one relation.

The first molding member 150 is formed on the first lead frame 120 to cover the first semiconductor chip 130 and the first conductive wires 140. Here, ends of the first outer leads 122 are exposed through side faces of the first molding member 150. Further, lower surfaces of the first outer leads 122 may be exposed by the first molding member 150.

The first molding member 150 may protect the first semiconductor chip 130 and the first conductive wires 140 from external impacts. Further, the first molding member 150 may electrically insulate the first semiconductor chip 130 and the first conductive wires 140 from the outside. In this example embodiment, the first molding member 150 may include epoxy resin.

The second semiconductor package 210 is stacked on the first semiconductor package 110. The second semiconductor package 210 includes a second lead frame 220, a second semiconductor chip 230, second conductive wires 240 and a second molding member 250. In this example embodiment, the second semiconductor chip 230, the second conductive wires 240 and the second molding member 250 of the second semiconductor package 210 except for the second lead frame 220 may be substantially the same as the first semiconductor chip 130, the first conductive wires 140 and the first molding member 150, respectively. Thus, any further illustrations with respect to the second semiconductor chip 230, the second conductive wires 240 and the second molding member 250 of the second semiconductor package 210 are omitted herein for brevity.

The second lead frame 220 has second outer leads 222. The second outer leads 222 include second central outer leads 224 arranged at a central portion of the second lead frame 220, and second outermost leads 226 arranged at an edge portion of the second lead frame 220. In this example embodiment, the second central outer leads 224 and the second outermost leads 226 may have an upwardly bent shape such as an “L” shape.

The conductive connection member 300 includes a first connection portion 310 and a second connection portion 320. In this example embodiment, the conductive connection member 300 may include solder. The first connection portion 310 surrounds the L-shaped first central outer leads 124 and the L-shaped second central outer leads 224 to electrically connect the first central outer leads 124 and the second central outer leads 224 to each other. Thus, the first semiconductor chip 130 and the second semiconductor chip 230 are electrically connected to each other through the conductive connection member 300.

The second connection portion 320 surrounds only the linear first outermost leads 126. Further, the second connection portion 320 is not formed on the second outermost leads 226 upwardly adjacent to the first outermost leads 126. Thus, the first outermost leads 126 and the second outermost leads 226 are not electrically connected to each other. Here, the first outermost leads 126 of the first semiconductor package 110 may correspond to a dummy lead through which electrical signals do not pass. Thus, it is unnecessary to electrically connect the first outermost leads 126 to the second outermost leads 226. The second connection portion 320 on the upper surface of the first outermost leads 126 may have a sufficient thickness because of the linear shape.

Further, the conductive connection member 300 has a crack-blocking groove 302. The crack-blocking groove 302 may block continuous spreads of cracks generated in the conductive connection member 300. That is, since the cracks may not progress at the crack-blocking groove 302, the cracks may not spread to entire portions of the conductive connection member 300.

In this example embodiment, the crack-blocking groove 302 may be formed at portions of the conductive connection member 300 on the lower surfaces of the first outer leads 122. Further, the crack-blocking groove 302 may be formed through the conductive connection member 300 to expose portions of the lower surfaces of the first outer leads 122, so that the conductive connection member 300 may be divided into at least two portions by the crack-blocking groove 302. Therefore, the cracks generated in any one of the two portions may not progress any more at the crack-blocking groove 302 so that the cracks may not spread to the other portion of the conductive connection member 300. Here, the cracks may generally spread from a peripheral portion of the conductive connection member 300 to a central portion of the conductive connection member 300. Thus, to effectively block the spreads of the cracks, the crack-blocking groove 302 may be arranged along a direction substantially perpendicular to an extending direction of the first outer leads 122.

Further, the crack-blocking groove 302 may be formed at all of the first outer leads 122. Alternatively, the crack-blocking groove 302 may be formed in some but not all of the first outer leads 122, i.e., only at the first outermost leads 126 in which the cracks are generally concentrated.

The stacked semiconductor package 100 having the above-mentioned structure may be mounted to a printed circuit board (not shown) using an outer terminal such as a solder ball to form a semiconductor module.

In some example embodiments, a single semiconductor chip may be provided in a single semiconductor chip. Alternatively, the example embodiments of the present invention may be applied to a multi-chip package where a plurality of semiconductor chips is stacked. Further, the structure in which the two semiconductor packages may be stacked is explained. Alternatively, the example embodiments of the present invention may be applied to a stacked package in which at least three semiconductor packages are stacked.

According to some example embodiments, the crack-blocking groove may block the spreads of the cracks generated in the conductive connection member. Thus, electrical connection failures between the outer leads caused by damages of the conductive connection member may be suppressed. Further, since the outermost leads may have the linear shape, the conductive member on the linear outermost leads may have a sufficient thickness.

Method of Manufacturing a Stacked Semiconductor Package

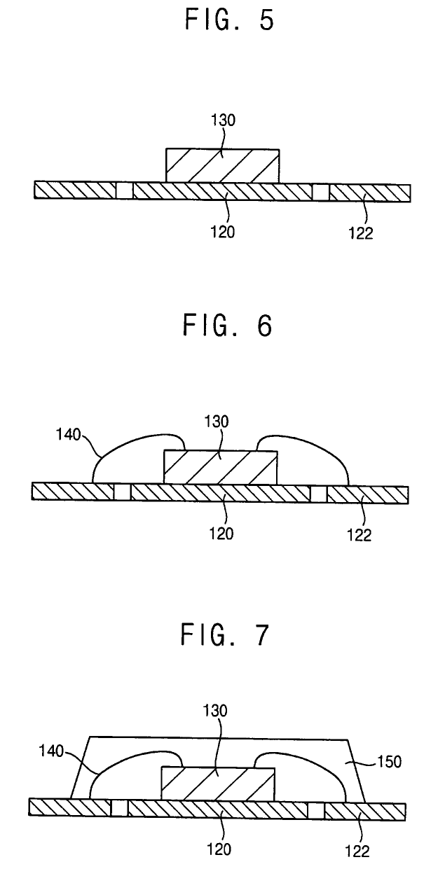

FIGS. 5 to 16 are cross-sectional views illustrating a method of manufacturing the stacked semiconductor package in FIG. 1.

First, processes for manufacturing the first semiconductor package 110 are illustrated with reference to FIGS. 5 to 8.

Referring to FIG. 5, the first semiconductor chip 130 is attached to the central upper surface of the first lead frame 120 using the adhesive. In this example embodiment, the first outer leads 122 of the first lead frame 120 may have a linear shape extending along the horizontal direction.

Referring to FIG. 6, first ends of the first conductive wires 140 are connected to the bonding pads of the first semiconductor chip 130. Second ends of the first conductive wires 140 opposite to the first ends are connected to the first outer leads 122. Thus, the first semiconductor chip 130 is electrically connected to the first outer leads 122 via the first conductive wires 140.

Referring to FIG. 7, the first molding member 150 is formed on the first lead frame 120 to cover the first semiconductor chip 130 and the first conductive wires 140. Here, the ends of the lower surfaces of the first outer leads 122 may be exposed by the first molding member 150.

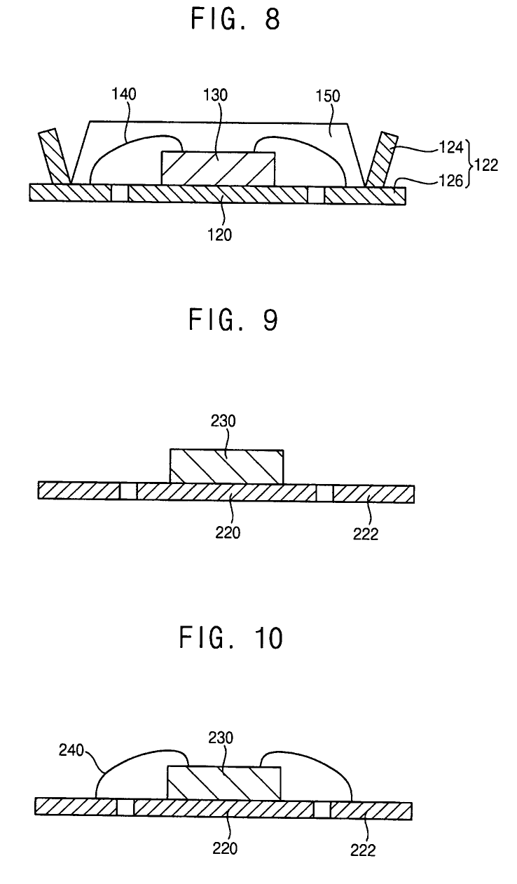

Referring to FIG. 8, the first central outer leads 124 are upwardly bent to form the L-shaped first central outer leads 124. Here, the first outermost leads 126 are not upwardly bent. Thus, the first outermost leads 126 still have the linear shape. Additionally, when the first outermost leads 126 are protruded from the first central outer leads 124, the ends of the first outermost leads 126 may be partially removed to provide the first linear outermost leads 126 and the first central outer leads 124 with substantially the same protruded length from the first molding member 150 to complete the first semiconductor package 110.

Processes for manufacturing the second semiconductor package 210 are illustrated with reference to FIGS. 9 to 12.

Referring to FIG. 9, the second semiconductor chip 230 is attached to the central upper surface of the second lead frame 220 using the adhesive.

Referring to FIG. 10, the bonding pads of the second semiconductor chip 230 and the second outer leads 222 are electrically connected to each other using the second conductive wires 240.

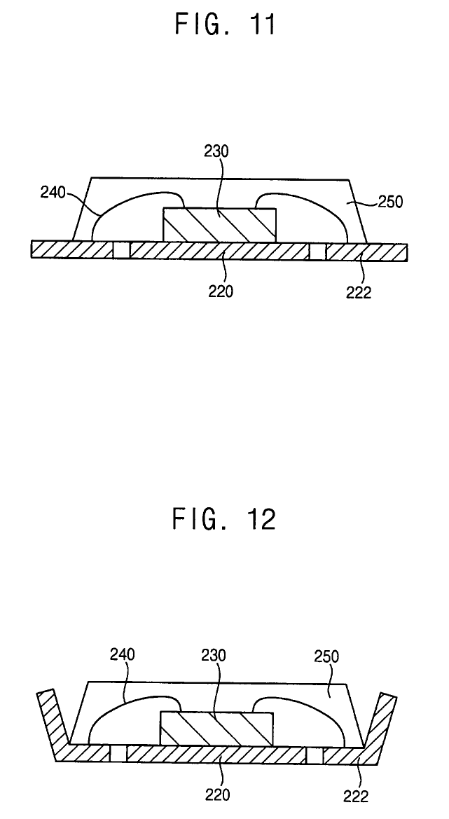

Referring to FIG. 11, the second molding member 250 is formed on the second lead frame 220 to cover the second semiconductor chip 230 and the second conductive wires 240.

Referring to FIG. 12, the second outer leads 222 are upwardly bent to form the L-shaped second outer leads 222 to complete the second semiconductor package 210.

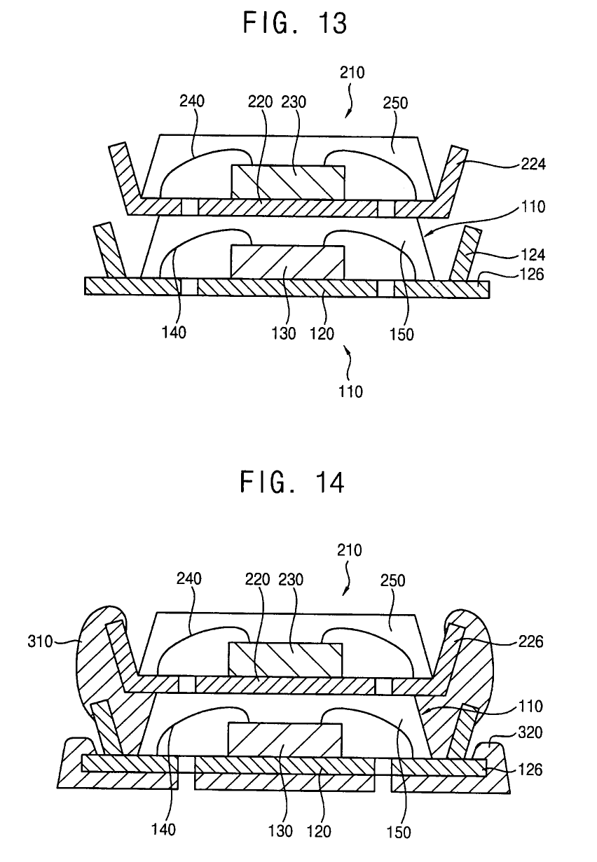

Referring to FIG. 13, the second semiconductor package 210 is stacked on the first semiconductor package 110. In this example embodiment, the second semiconductor package 210 may be attached to the first semiconductor package 110 using an adhesive.

Referring to FIG. 14, the conductive connection member 300, which includes the first connection portion 310 and the second connection portion 320, may surround the first outer leads 122 and the second outer leads 222 to electrically connect the first outer leads 122 and the second outer leads 222 to each other in a one-to-one relation. The conductive member 300 may be comprised of solder.

In some example embodiments, the conductive connection member 300 may surround only the first linear outermost leads 126. The conductive connection member 300 may not be formed on the second outermost leads 226 adjacent to the first outermost leads 126. Thus, the first outermost leads 126 may not be electrically connected to the second outermost leads 226. As a result, the second connection portion 320 on the flat upper surface of the first linear outermost leads 126 may have a sufficient thickness because of the linear shape.

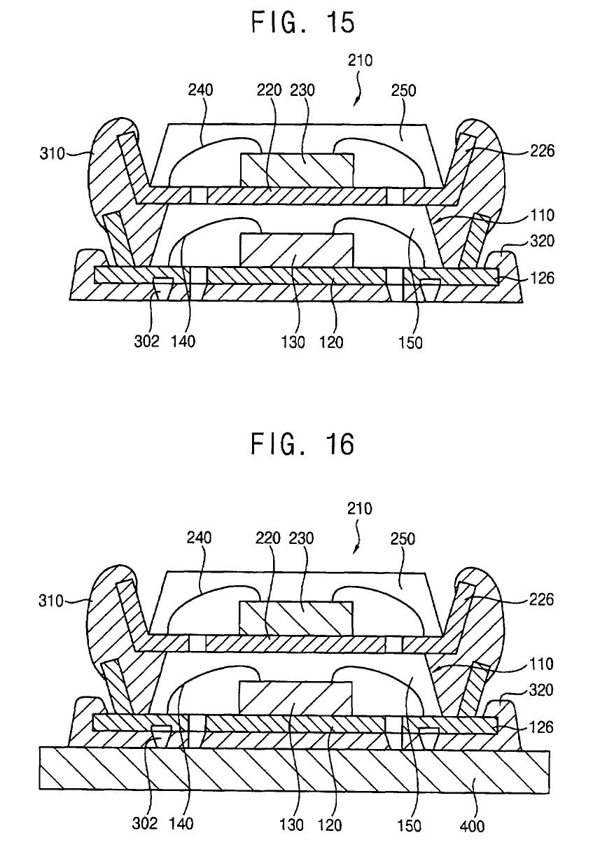

Referring to FIG. 15, the lower surface of the conductive connection member 300 is partially removed to form the crack-blocking groove 302 exposing portions of the lower surfaces of the first outer leads 122. In some example embodiments, the conductive connection member 300 may be removed by an etching process. Accordingly, the stacked semiconductor package 100 in FIG. 1 may be completed.

Referring to FIG. 16, the stacked semiconductor package 100 is mounted on a printed circuit board using outer terminals such as a solder ball to complete a semiconductor module.

According to some embodiments of the present invention, the crack-blocking groove may block the spreads of the cracks generated in the conductive connection member. Thus, the electrical connection failures between the outer leads caused by the damages of the conductive connection member may be suppressed.

Further, the outermost leads may have the linear shape so that the conductive connection member on the flat upper surface of the linear outermost leads may have a sufficient thickness.

The foregoing is illustrative of the present invention and is not to be construed as limiting thereof. Although a few embodiments of the present invention have been described, those skilled in the art will readily appreciate that many modifications are possible in the embodiments without materially departing from the novel teachings and advantages of this invention. Accordingly, all such modifications are intended to be included within the scope of the present invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A stacked semiconductor package comprising:
a first semiconductor package including a first semiconductor chip, a first lead frame having first outer leads that are electrically connected to the first semiconductor chip, and a first molding member formed on the first semiconductor chip and the first lead frame to expose the first outer leads;
a second semiconductor package including a second semiconductor chip, a second lead frame arranged on the first molding member and having second outer leads that are electrically connected to the second semiconductor chip, and a second molding member formed on the second semiconductor chip and the second lead frame to expose the second outer leads; and
a conductive connection member electrically connecting the first outer leads and the second outer leads exposed by the first molding member and the second molding member, respectively, the conductive connection member having a crack-blocking groove.

2. The stacked semiconductor package of claim 1, wherein the first outer leads have lower surfaces exposed by the first molding member, and wherein the crack-blocking groove is formed at portions of the conductive connection member on the lower surfaces of the first outer leads.

3. The stacked semiconductor package of claim 1, wherein the crack-blocking groove is substantially perpendicular to an extending direction of the first outer leads.

4. The stacked semiconductor package of claim 1, wherein the crack-blocking groove exposes portions of the first outer leads and divides the conductive connection member into at least two portions.

5. The stacked semiconductor package of claim 1, wherein first outermost leads of the first outer leads have a linear shape extending along a horizontal direction, the first outermost leads being arranged at edges of the first semiconductor chip.

6. The stacked semiconductor package of claim 5, wherein the conductive connection member covers upper surfaces of the first linear outermost leads.

7. The stacked semiconductor package of claim 5, wherein the conductive connection member is formed only on the first linear outermost leads to electrically insulate the second outermost leads adjacent to the first linear outermost leads from the first linear outermost leads.

8. The stacked semiconductor package of claim 1, wherein the first semiconductor chip and the first outer leads are connected to each other using first conductive wires, and wherein the second semiconductor chip and the second outer leads are connected to each other using second conductive wires.

9. A stacked semiconductor package comprising:
a first semiconductor package including a first semiconductor chip, a first lead frame having first central outer leads that are electrically connected to the first semiconductor chip and first linear outermost leads that extend along a horizontal direction, and a first molding member formed on the first semiconductor chip and the first lead frame to expose the first central outer leads and the first outermost leads;
a second semiconductor package including a second semiconductor chip, a second lead frame arranged on the first molding member and having second outer leads that are electrically connected to the second semiconductor chip, and a second molding member formed on the second semiconductor chip and the second lead frame to expose the second outer leads; and
a conductive connection member formed on the exposed first central outer leads and the exposed second outer leads to electrically connect the exposed first central outer leads and the exposed second outer leads.

10. The stacked semiconductor package of claim 9, wherein the conductive connection member is formed only on the first linear outermost leads to electrically insulate the first linear outermost leads from the second outer leads adjacent to the first linear outermost leads.

11. The stacked semiconductor package of claim 9, wherein the conductive connection member covers upper surfaces of the first linear outermost leads.

12. A stacked semiconductor package comprising:
a first semiconductor package comprising:
a first semiconductor chip;
a first lead frame having first outer leads, the first outer leads including first central outer leads and first outermost leads; and
a first molding member formed on the first semiconductor chip and the first lead frame,
wherein the first outer leads are electrically connected to the first semiconductor chip, wherein the first central outer leads have an “L” shape, and wherein the first outermost leads have a linear shape extending along a horizontal direction; and
a second semiconductor package comprising:
a second semiconductor chip; and
a second lead frame arranged on the first molding member and having second outer leads that are electrically connected to the second semiconductor chip, and a second molding member formed on the second semiconductor chip and the second lead frame to expose the second outer leads.

13. The stacked semiconductor package of claim 12, further comprising:
a first conductive connection portion electrically connecting the first central outer leads and the second outer leads exposed by the first molding member and the second molding member, respectively.

14. The stacked semiconductor package of claim 13, further comprising:
a second conductive connection portion surrounding the linear first outermost leads, the second conductive connection portion not being formed on the second outer leads.

15. The stacked semiconductor package of claim 12, wherein the linear first outermost leads correspond to dummy leads through which electrical signals do not pass.

16. The stacked semiconductor package of claim 14, further comprising at least one crack-blocking groove formed in the first outer leads.

17. The stacked semiconductor package of claim 16, wherein the at least one crack-blocking groove is formed in the second conductive connection portion.

18. The stacked semiconductor package of claim 16, wherein the at least one crack-blocking groove is arranged along a direction substantially perpendicular to an extending direction of the first outer leads.

19. The stacked semiconductor package of claim 16, wherein the at least one crack-blocking groove is formed in all of the first outer leads.

20. The stacked semiconductor package of claim 16, wherein the at least one crack-blocking groove is formed in some but not all of the first outer leads.
